(19) United States
(12) Patent Application Publication
(10) Pub. No.: US 2012/0195118 A1
(43) Pub. Date: Aug. 2, 2012

(54) SEMICONDUCTOR MEMORY APPARATUS, DATA PROGRAMMING METHOD THEREOF, AND MEMORY SYSTEM INCLUDING THE SAME

(75) Inventor: Chang Won YANG, Icheon-si (KR)

(73) Assignee: HYNIX SEMICONDUCTOR INC., Icheon-si (KR)

(21) Appl. No.: 13/340,917

(22) Filed: Dec. 30, 2011

(30) Foreign Application Priority Data
Jan. 31, 2011 (KR) 10-2011-0009810

(51) Int. Cl. G11C 16/10

(52) U.S. Cl. 365/185.03

(57) ABSTRACT

A semiconductor memory apparatus includes: a memory unit including a first memory group and a second memory group; and a control unit configured to control input data to be programmed into selected memory cells of the first memory group such that one-bit data is programmed into each of the memory cells of the first memory group when the size of the input data is smaller than a size of data which may be stored into the first memory group during a programming mode, and control the input data programmed in the first memory group to be reprogrammed into selected memory cells of the second memory group during a standby mode after the programming mode, such that multi-bit data are programmed into each of the memory cells of the selected second memory group.

### CROSS-REFERENCES TO RELATED APPLICATION

The present application claims priority under 35 U.S.C. §119(a) to Korean application number 10-2011-0009810, filed on Jan. 31, 2011, in the Korean Intellectual Property Office, which is incorporated herein by reference in its entirety as set forth in full.

### BACKGROUND

1. Technical Field

The present invention relates to a semiconductor memory apparatus, and more particularly, to technology for programming data into a memory cell.

2. Related Art

In order to increase the integration degree of a nonvolatile memory apparatus, a multi-bit cell capable of storing a plurality of data in one memory cell is used. A memory cell capable of storing multi-bit data is referred to as a multi-level cell (MLC), and a memory cell capable of storing single-bit data is referred to as a single-level cell (SLC).

For reference, an SLC capable of storing data corresponding to one bit has two threshold voltage distributions. Meanwhile, an MLC capable of storing data corresponding to three bits has eight threshold voltage distributions, and an MLC capable of storing data corresponding to four bits has 16 threshold voltage distributions.

Because an MLC stores multi-bit data in one memory cell, the MLC has an advantage in terms of storage capacity. However, the MLC requires a larger amount of programming time than the SLC.

### SUMMARY

A semiconductor memory apparatus and a data programming method, which are capable of improving a programming speed by using a part of MLCs like SLCs, are described herein.

In one embodiment of the present invention, a semiconductor memory apparatus includes: a memory unit including a first memory group and a second memory group; and a control unit configured to control input data to be programmed into selected memory cells of the first memory group such that one-bit data is programmed into each of the memory cells of the first memory group, when the size of the input data is smaller than a size of data which may be stored into the first memory group during a programming mode, and control the input data programmed in the first memory group to be reprogrammed into selected memory cells of the second memory group during a standby mode after the programming mode, such that multi-bit data are programmed into each of the selected memory cells of the second memory group.

In another embodiment of the present invention, there is provided a data programming method which programs data into first and second memory groups. The data programming method includes the steps of: determining when a size of input data is smaller than a size of data which may be stored by the first memory group during a programming mode and if so, programming the input data into selected memory cells of the first memory group such that one-bit data is programmed into each of the memory cells of the first memory group; and reprogramming the input data programmed in the first memory group into selected memory cells of the second memory group during a standby mode after the programming mode, such that multi-bit data are programmed into each of the selected memory cells of the second memory group.

In another embodiment of the present invention, a memory system includes: a host apparatus; and a semiconductor memory apparatus configured to store data provided from the host apparatus or provide stored data to the host apparatus. The semiconductor memory apparatus includes a memory unit having first and second memory groups and a control unit configured to control the memory unit. When a size of the data provided from the host apparatus is smaller than a storage capacity of the first memory group, the control unit controls the memory unit to program the provided data into the first memory group in a single level scheme, and while no operation is requested from the host apparatus, the control unit controls the memory unit to read the data programmed in the first memory group and program the read data into the second memory group in a multi-level scheme.

### BRIEF DESCRIPTION OF THE DRAWINGS

Features, aspects, and embodiments are described in conjunction with the attached drawings, in which:

FIG. 1 is a conceptual diagram of a semiconductor memory apparatus according to one embodiment; and

FIG. 2 is a flow chart showing a data programming method of the semiconductor memory apparatus of FIG. 1.

### DETAILED DESCRIPTION

Hereinafter, a semiconductor memory apparatus, a data programming method thereof, and a memory system including the same according to the present invention will be described below with reference to the accompanying drawings through exemplary embodiments.

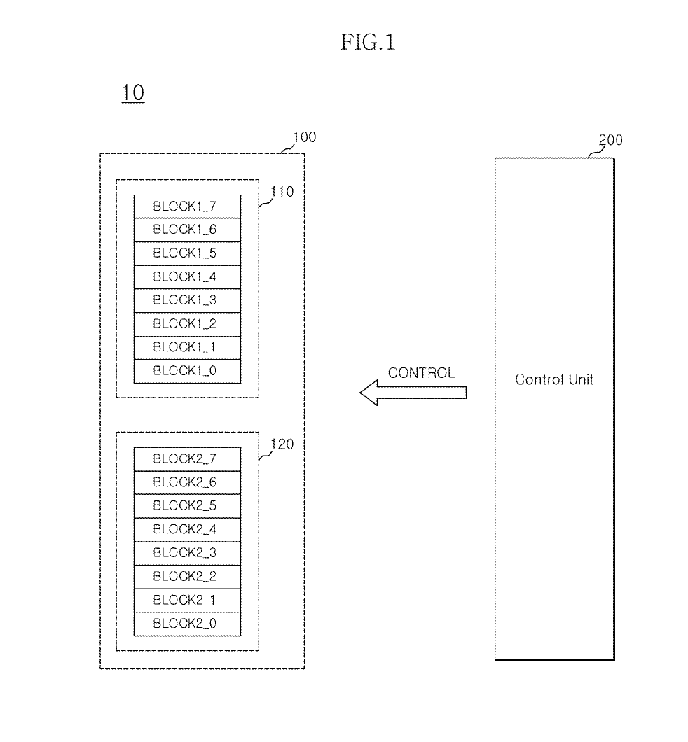

FIG. 1 is a conceptual diagram of a semiconductor memory apparatus according to one embodiment.

The semiconductor memory apparatus according to the embodiment includes only simple components for clearly explaining the technical idea of an embodiment of the present invention.

Referring to FIG. 1, the semiconductor memory apparatus 10 includes a memory unit 100 and a control unit 200.

The semiconductor memory apparatus 10 is configured to store data provided from an external apparatus, for example, a host apparatus or provide stored data to the external apparatus, according to a request from the external apparatus.

The memory unit 100 includes a group having one or more memory blocks. For example, the memory unit 100 may include a first memory group 110 and a second memory group 120. The first memory group 110 may include a plurality of memory blocks BLOCK1_0 to BLOCK1_7. The second memory group 120 may include a plurality of memory blocks BLOCK2_0 to BLOCK2_7. Here, it is assumed that each of the first and second memory blocks includes a plurality of flash memory cells. Furthermore, it is assumed that a flash memory cell is basically formed using a multi-level cell (MLC) capable of storing multi-bit data. For another example, the flash memory cells of the first memory group 110 may be formed using a single level cell (SLC), and the flash memory cells of the second memory group 120 may be formed using an MLC. Therefore, the program speed of the first memory group 110 is higher than the program speed of the second memory group 120.

The control unit 200 is configured to control an operation of the memory unit 100. Furthermore, the control unit 200 may be configured to control a cache (or buffer) program operation for the memory unit 100.

When the size of input data is smaller than the size of data which may be stored by or in the first memory group 110 during a programming mode, the control unit 200 controls the input data to be programmed into selected memory cells of the first memory group 110. At this time, the control unit 200 controls one-bit data to be programmed into each of the memory cells of the first memory group 110. That is, although each of the memory cells is configured as an MLC, the memory cell stores only one-bit data like an SLC such that the data may be quickly programmed.

Furthermore, the control unit 200 controls the input data programmed in the first memory group 110 to be reprogrammed into selected memory cells of the second memory group 120 during a standby mode after the programming mode. The standby mode corresponds to an operation mode when no operation is requested from an external apparatus such as a host apparatus. At this time, the control unit 200 controls multi-bit data into each of the memory cells of the second memory group 120. For example, the control unit 200 may control the memory unit 100 such that the data programmed in the first memory group 110 are read and then programmed the read data into the selected memory cells of the second memory group 120, during the standby mode.

Furthermore, the control unit 200 controls an erase operation to be performed on the memory cells of the first memory group 110 in which the input data are stored, after the input data programmed in the first memory group 110 are programmed into the selected memory cells of the second memory group 120. That is, it can be considered from the position of the external apparatus of the semiconductor memory apparatus 10 that the input data are programmed at a speed where the input data are programmed into an SLC. Furthermore, since the semiconductor memory apparatus 10 reprograms the input data by multi-bit data into the MLC during the standby mode after the programming mode, it is possible to maintain the capacity of the memory unit 100.

When, however, the size of the input data is larger than the size of the data which may be stored by the first memory group 110 during the programming mode, the control unit 200 controls a part of the input data, which corresponds to the size of the data which may be stored by the first memory group 110, to be programmed into the memory cells of the first memory group 110. At this time, the control unit 200 controls one-bit data to be programmed into each of the memory cells of the first memory group 110. The control unit 200 controls the rest of (remainder of) the input data, which exceeds the size of the data which may be stored by the first memory group 110, to be programmed into selected memory cells of the second memory group 120. When programming the remainder of the input data, the control unit 200 controls multi-bit data to be programmed into each of the memory cells of the second memory group 120.

Furthermore, when effective data are stored in all of the memory cells of the second memory group 120 during the programming mode, the control unit 200 controls the input data to be programmed into memory cells selected from the first memory group 110. At this time, the control unit 200 controls multi-bit data to be programmed into each of the memory cells of the first memory group 110.

In short, the semiconductor memory apparatus 10 according to an embodiment may maintain the storage capacity of the MLC, while having the programming speed of the SLC.

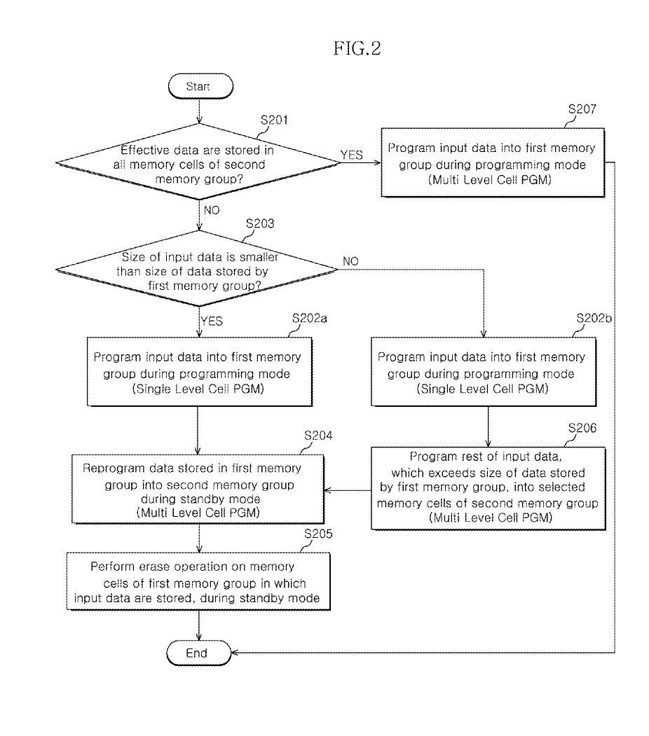

FIG. 2 is a flow chart showing a data programming method of the semiconductor memory apparatus of FIG. 1.

Referring to FIGS. 1 and 2, a method for programming data into the first memory group 110 and the second memory group 120 may be divided into a case in which the size of input data is smaller than the size of data which may be stored by the first memory group 110 during the programming mode and a case in which the size of input data is larger than the size of data which may be stored by the first memory group 110 during the programming mode. First, when the size of input data is smaller than the size of the data which may be stored by the first memory group 110 during the programming mode, the data programming method includes the steps of: programming the input data into selected memory cells of the first memory group 110 such that one-bit data is programmed into each of the memory cells; and reprogramming the input data programmed in the first memory group 110 into selected memory cells of the second memory group 120 during a standby mode after the programming mode, such that multi-bit data are programmed into each of the memory cells of the second memory group 120.

Furthermore, the data programming method includes the step of performing an erase operation on the memory cells of the first memory group 110 in which the input data are stored, after the input data programmed in the first memory group 110 are reprogrammed into the selected memory cells of the second memory group 120.

Next, when the size of input data is larger than the size of the data which may be stored by the first memory group 110 during the programming mode, the data programming method includes the steps of: programming a part of the input data, which corresponds to the size of the data which may be stored by the first memory group 110, into the memory cells of the first memory group 110 such that one-bit data is programmed into each of the memory cells of the first memory group 110; and programming the rest of the input data, which exceeds the size of the data which may be stored by the first memory group 110, into selected memory cells of the second memory group 120 such that multi-bit data are stored in each of the memory cells of the second memory group 120.

Furthermore, the data programming method includes the step of programming the input data into selected memory cells of the first memory group 110 such that multi-bit data are programmed into each of the memory cells of the first memory group 110, when effective data are stored in all of the memory cells of the second memory group 120 during the programming mode.

The above-described data programming method may be described in more detail as follows.

First, whether effective data are stored in all of the memory cells of the second memory group 120 during the programming mode is determined at step S201. At this time, when the second memory group 120 has no space capable of storing data because effective data are stored in all of the memory cells of the second memory group 120, input data are programmed into the first memory group 110 at step S207. At this time, multi-bit data are programmed into each of the memory cells of the first memory group 110.

When the second memory group 120 secures a space capable of storing data because effective data are not stored in all of the memory cells of the second memory group 120, the operation is performed as follows.

First, whether the size of the input data is smaller than the size of the data which may be stored by the first memory group 110 is determined at step S203. If the size of the input data is smaller than the size of the data which may be stored by the first memory group 110 during a programming mode, the control unit 200 controls the input data to be programmed into selected memory cells of the first memory group 110, at step 202a. At this time, one-bit data is programmed into each of the memory cells of the first memory group 110, thereby improving the programming speed.

If, however, if it is determined at step 203 that the size of the input data is larger than the size of the data which may be stored by the first memory group 110 during the programming mode, the control unit 200 controls a part of the input data, which corresponds to the size of the data which may be stored by the first memory group 110, to be programmed into the memory cells of the first memory group 110, at step 202b; and the remainder of the input data which exceeds the size of the data which may be stored by the first memory group 110 is programmed into selected memory cells of the second memory group 120, at step S206. At this time, the control unit 200 controls one-bit data to be programmed into each of the memory cells of the first memory group 110, and multi-bit data are programmed into each of the memory cells of the second memory group 120.

When all of the input data are stored in the first memory group 110, the input data programmed in the first memory group 110 in steps S202a or S202b are reprogrammed into selected memory cells of the second memory group 120 during the standby mode, at step S204. At this time, multi-bit data are programmed into each of the memory cells of the second memory group 120 so as to secure a storage capacity.

After the input data programmed in the first memory group 110 are reprogrammed into the selected memory cells of the second memory group 120 (S204), an erase operation is performed on the memory cells of the first memory group 110 in which the input data are stored, at step S205. That is, the first memory group 110 is used as a kind of cache.

Through the semiconductor memory apparatus 10 and the data programming method, data may be programmed into an MLC at the programming speed of the SLC, and the storage capacity of the MLC may be maintained. Therefore, the semiconductor memory apparatus 10 and the data programming method may be usefully used in an application requiring a high programming speed.

While certain embodiments have been described above, it will be understood to those skilled in the art that the embodiments described are by way of example only. Accordingly, the semiconductor memory apparatus and the data programming method described herein should not be limited based on the described embodiments. Rather, the semiconductor memory apparatus and the data programming method described herein should only be limited in light of the claims that follow when taken in conjunction with the above description and accompanying drawings.

What is claimed is:

1. A semiconductor memory apparatus comprising:
a memory unit comprising a first memory group and a second memory group; and
a control unit configured to control input data to be programmed into selected memory cells of the first memory group such that one-bit data is programmed into each of the memory cells of the first memory group when the size of the input data is smaller than a size of data which may be stored into the first memory group during a programming mode, and control the input data programmed in the first memory group to be reprogrammed into selected memory cells of the second memory group during a standby mode after the programming mode, such that multi-bit data are programmed into each of the selected memory cells of the second memory group.

2. The semiconductor memory apparatus according to claim 1, wherein: the control unit controls an erase operation to be performed on the memory cells of the first memory group, after the input data programmed in the first memory group are reprogrammed into the selected memory cells of the second memory group.

3. The semiconductor memory apparatus according to claim 1, wherein: when the size of the input data is larger than a size of data which may be stored by the first memory group during the programming mode, the control unit controls a part of the input data, which corresponds to a size of the data which may be stored into the first memory group, to be programmed into the memory cells of the first memory group such that one-bit data is programmed into each of the memory cells of the first memory group, and controls a remainder of the input data, which exceeds the size of the data which is stored by the first memory group, to be programmed into selected memory cells of the second memory group such that multi-bit data are programmed into each of the memory cells of the second memory group.

4. The semiconductor memory apparatus according to claim 1, wherein: when effective data are stored in all of the memory cells of the second memory group during the programming mode, the control unit controls the input data to be programmed into selected memory cells of the first memory group such that multi-bit data are programmed into each of the memory cells of the first memory group.

5. The semiconductor memory apparatus according to claim 1, wherein: the first memory group comprises one or more memory blocks each having a memory cell which is programmed in a single level scheme, and
the second memory group comprises one or more memory blocks each having a memory cell which is programmed in a multi-level scheme.

6. The semiconductor memory apparatus according to claim 1, wherein:
before one-bit data is programmed into each of the memory cells of the first memory group when the size of the input data is smaller than a size of data which may be stored into the first memory group during a programming mode, determining if effective data are stored in all of the memory cells of the second memory group and if so, programming the input data into the first memory group such that multi-bit data are programmed into each of the memory cells of the first memory group.

7. A data programming method which programs data into first and second memory groups, comprising the steps of:
determining when a size of input data is smaller than a size of data which may be stored by the first memory group during a programming mode and if so, programming the input data into selected memory cells of the first memory group such that one-bit data is programmed into each of the memory cells of the first memory group; and
reprogramming the input data programmed in the first memory group into selected memory cells of the second memory group during a standby mode after the programming mode, such that multi-bit data are programmed into each of the selected memory cells of the second memory group.

8. The data programming method according to claim 7, further comprising the step of: performing an erase operation on the memory cells of the first memory group, after the input data programmed in the first memory group are reprogrammed into the selected memory cells of the second memory group.

9. The data programming method according to claim 7, further comprising the step of: when the size of the input data is larger than a size of the data which may be stored by the first memory group during the programming mode, programming a part of the input data, which corresponds to the size of the data which may be stored by the first memory group, into the memory cells of the first memory group such that one-bit data is programmed into each of the memory cells of the first memory group, and programming a remainder of the input data, which exceeds the size of the data which is stored by the first memory group, into selected memory cells of the second memory group such that multi-bit data are programmed into each of the memory cells of the second memory group.

10. The data programming method according to claim 7, further comprising the step of: when effective data are stored in all memory cells of the second memory group during the programming mode, programming the input data into selected memory cells of the first memory group such that multi-bit data are programmed into each of the memory cells of the first memory group.

11. The data programming method according to claim 7, further comprising before determining when the size of input data is smaller than the size of data which may be stored by the first memory group during a programming mode:
determining if effective data are stored in all of the memory cells of the second memory group and if so, programming the input data into the first memory group such that multi-bit data are programmed into each of the memory cells of the first memory group.

12. A memory system comprising:
a host apparatus; and
a semiconductor memory apparatus configured to store data provided from the host apparatus or provide stored data to the host apparatus,
wherein the semiconductor memory apparatus comprises a memory unit having first and second memory groups and a control unit configured to control the memory unit,
when a size of the data provided from the host apparatus is smaller than a storage capacity of the first memory group, the control unit controls the memory unit to program the provided data into the first memory group in a single level scheme, and
while no operation is requested from the host apparatus, the control unit controls the memory unit to read the data programmed in the first memory group and program the read data into the second memory group in a multi-level scheme.

13. The memory system according to claim 12, wherein the control unit controls the memory unit to erase the first memory group, after the read data are programmed into the second memory group.

14. The memory system according to claim 12, wherein, when a size of the provided data is larger than the storage capacity of the first memory group, the control unit controls the memory unit such that a part of the provided data, which corresponds to the storage capacity of the first memory group, is programmed into the first memory group in the single level scheme and the rest of the provided data is programmed into the second memory group in the multi-level scheme.

15. The memory system according to claim 12, wherein, when determining that effective data are stored in all memory cells of the second memory group, the control unit controls the memory unit to program the provided data into the first memory group in the multi-level scheme.

16. A semiconductor memory apparatus comprising:
a memory unit comprising a first memory group which has a first programming time and a second memory group which has a second programming time longer than the first programming time; and
a control unit configured to control the memory unit,
wherein, when a size of the data provided from the host apparatus is smaller than a storage capacity of the first memory group, the control unit controls the memory unit to program the provided data into the first memory group in a single level scheme, and
while no operation is requested from the host apparatus, the control unit controls the memory unit to read the data programmed in the first memory group and program the read data into the second memory group in a multi-level scheme.

17. The semiconductor memory apparatus according to claim 16, wherein the control unit controls the memory unit to erase the first memory group, after the read data are programmed into the second memory group.

18. The semiconductor memory apparatus according to claim 16, wherein, when a size of the provided data is larger than the storage capacity of the first memory group, the control unit controls the memory unit such that a part of the provided data, which corresponds to the storage capacity of the first memory group, is programmed into the first memory group in the single level scheme and the rest of the provided data is programmed into the second memory group in the multi-level scheme.

19. The semiconductor memory apparatus according to claim 16, wherein, when determining that effective data are stored in all memory cells of the second memory group, the control unit controls the memory unit to program the provided data into the first memory group in the multi-level scheme.

20. A semiconductor memory apparatus comprising:
a first memory block;
a second memory block; and
a control unit configured to control the first memory block and the second memory block,
wherein, when a size of the data provided from an external apparatus is smaller than a storage capacity of the first memory block, the control unit programs the provided data into the first memory block in a single level scheme, and
while no operation is requested from the external apparatus, the control unit reads the provided data from the first memory block and programs the read data into the second memory block in a multi-level scheme.

21. The semiconductor memory apparatus according to claim 20, wherein the control unit erases the first memory block, after the read data are programmed into the second memory block.

22. The semiconductor memory apparatus according to claim 20, wherein, when a size of the provided data is larger than the storage capacity of the first memory block, the control unit programs a part of the provided data, which corresponds to the storage capacity of the first memory block, into the first memory block in the single level scheme and programs the rest of the provided data into the second memory block in the multi-level scheme.

23. The semiconductor memory apparatus according to claim 20, wherein, when determining that effective data are stored in all memory cells of the second memory block, the control unit programs the provided data into the first memory block in the multi-level scheme.
